(19) United States
(12) Patent Application Publication
(10) Pub. No.: US 2011/0226860 A1
(43) Pub. Date: Sep. 22, 2011

(54) PRINTED CIRCUIT BOARD WITH ANTENNA FOR RFID CHIP AND METHOD FOR MANUFACTURING THE SAME

(75) Inventors: CHEN-JYH FAN, Hsinchu County (TW); Hui-Chuan Chen, Hsinchu City (TW); Ching-Tsung Cheng, Taipei County (TW)

(73) Assignee: Industrial Technology Research Institute, Hsinchu (TW)

(21) Appl. No.: 12/830,095

(22) Filed: Jul. 2, 2010

(30) Foreign Application Priority Data
Mar. 16, 2010 (TW) 099107604

(51) Int. Cl. G06K 19/067; H05K 7/00; H05K 3/30

(52) U.S. Cl. 235/492; 361/783; 29/832

(57) ABSTRACT

A printed circuit board with an antenna for an RFID chip and a method for manufacturing the printed circuit board are provided. The method includes steps of providing a printed circuit board whereon a metal foil layer is disposed; patterning the metal foil layer to form an antenna comprising a first antenna branch and a second antenna branch, wherein the first antenna branch has at least two right-angle turns; and mounting an RFID chip on the metal foil layer so as to be electrically connected to the first antenna branch and the second antenna branch, wherein a via hole is formed between the right-angle turns of the first antenna branch, so that the first antenna branch is electrically connected to a metal conductor inside or on the back of the printed circuit board through the via hole.

### TECHNICAL FIELD

The present disclosure relates to a printed circuit board for RFID applications, and more particularly, to an antenna structure of the printed circuit board.

### TECHNICAL BACKGROUND

Production tracing has been a common consensus for worldwide manufacturers. Its development is mainly focused on the food industry as a pioneer, and will be followed out to the other industries. As the timing of the RoHS (Restriction of Hazardous Substances) is getting urgent, the manufacturers have been planning to apply the radio frequency identification device (RFID) onto a printed circuit board (PCB) and to record production matters of a product, so that the European Union (EU) customers can read them and meet the EU RoHS requirements.

The data carrier of production tracing in the food industry is presently based on barcodes due to cost considerations. Barcodes carry very limited information about a product. In the electronic industry, however, the amount of electronic components mounted on a PCB is huge; therefore, the RFID could be the best choice for manufacturers. Except for the production tracing, a PCB can be colored in different board areas to remark their corresponding possibility for environmental pollutions, so as to facilitate the scrapping process for scrapped products.

An RFID on a PCB can be also used in the field of lifetime management. For example, the regulations of the WEEE (Waste from Electrical and Electronic Equipment) require that the manufacturers are responsible for recycling and appropriately processing the scrapped electrical and electronic products. An RFID can be used to trace the scrapped products as a mechanism of waste management. In the medical industry, the RFID technology has been exploited to monitor medical waste such as syringe needles or medicinal liquid, which may cause further inflections. With art-of-the-state information technology, the operational modes of RFID, which are originally developed for the green ecology, can be fine tuned to fit for the other applications. Therefore RFID has been interesting to manufacturers who are willing to involve themselves in the EU market.

Regarding to the present development of RFID technology, RFID applications in the industrial supply chain did not work well due to high chip price, insufficient identifiability, and need to attach RFID tags by hand. Even the Wal-Mart was forced to change his strategic plan to dispose an RFID tag on per packing box or per container instead on per single retail goods.

These days RFID tags are mostly fabricated by the method of roll-to-roll transfer and consist of polyethylene, which is not durable for high temperature. The Taiwan patent (I240210) disclosed a method of assembling RFID modules, wherein a chip die is taken by means of flip-chip or ejector-pin method to be attached on a polypropylene tape via UV-curable epoxy. This method can by applied to a packing box or a container, but the joiner of the RFID module is not durable for high temperature. Moreover, its readability and cost advantage can be further improved.

To reduce sizes of RFID tags, an RFID chip or an RFID tag without internal antenna was provided. An antenna may be provided on a PCB. The US patent (U.S. Pat. No. 7,432,816) disclosed a PCB with an RFID antenna, as shown in FIG. 1, wherein a PCB 100 is provided with a connector 121 to connect an RFID chip 120 and the antenna can be dipole-type derivatives. The RFID chip 120, having the main identification circuit, transmits and/or receives information through the antenna 110 on the PCB 100. An RFID chip not including an internal antenna has much smaller size and less cost than a conventional RFID tag. However, the dipole antenna is easy to be interfered electromagnetically by the components and metal conductors in the PCB, so that readability of the RFID chip is limited.

### TECHNICAL SUMMARY

This disclosure discloses a printed circuit board with an antenna for an RFID chip and a method for manufacturing the printed circuit board. To mount an RFID chip on a PCB using the conventional mounting method such as the surface mounting technology (SMT), the impedance stability of a RFID tag is increased and thereby its readability is enhanced.

In one aspect of the invention, the disclosure provides a method for manufacturing a PCB with an antenna for an RFID chip, comprising the following steps of: providing a printed circuit board whereon a metal foil layer is disposed; patterning the metal foil layer to form an antenna comprising a first antenna branch and a second antenna branch, wherein the first antenna branch has at least two right-angle turns; and mounting an RFID chip on the metal foil layer so as to be electrically connected to the first antenna branch and the second antenna branch, wherein a via hole is formed between the right-angle turns of the first antenna branch, so that the first antenna branch is electrically connected to a metal conductor inside or on the back of the printed circuit board through the via hole.

In another aspect of the invention, the disclosure provides a PCB with an antenna for an RFID chip, comprising: a PCB with a patterned metal foil layer thereon as an antenna, the antenna comprising a first antenna branch and a second antenna branch, wherein the first antenna branch has at least two right-angle turns; an RFID chip, mounted on the metal foil layer through a connector so as to electrically connect the first antenna branch and the second antenna branch; and a via hole in the PCB and between the right-angle turns of the first antenna branch, so as to electrically connect the first antenna branch and a metal conductor inside or on the back of the PCB through the via hole.

### BRIEF DESCRIPTION OF THE DRAWINGS

Referring to the following description and accompanying drawings that are used to illustrate embodiments of the invention may understand the disclosure.

FIG. 1 shows a side view of the PCB with an antenna, disclosed by the US patent (U.S. Pat. No. 7,432,816).

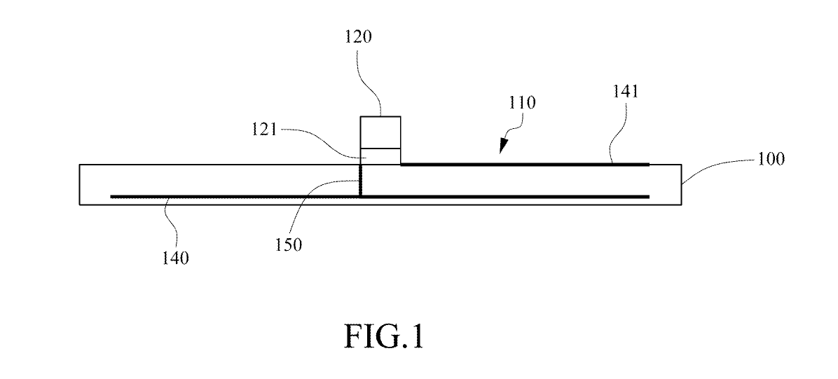

FIG. 2 shows a flowchart of a method for manufacturing a PCB with an antenna for an RFID chip, according to an embodiment.

FIG. 3 shows a perspective view of a PCB with an antenna for an RFID chip, according to an embodiment.

FIG. 4 shows a side view of a PCB with a three-dimensional antenna for an RFID chip, according to an embodiment.

### DESCRIPTION OF THE EXEMPLARY EMBODIMENTS

The principles of the embodiments are described for illustrative purposes. However, one of ordinary skill in the art would readily recognize that the same principles are equally applicable to and can be implemented with variations that do not depart from the spirit and scope of the embodiments. In the following detailed description, references are made to the accompanying figures that illustrate specific embodiments.

This disclosure is applicable to the manufacturing process of a PCB, which mounts an RFID chip on a PCB using the SMT. An “RFID chip” means an RFID tag not including an internal antenna in the whole document. It is distinct from conventional thermo compression bonding or ultrasonic bonding, and can enhance the impedance stability of an RFID tag and thereby its readability. Meantime the cost of an RFID tag can be lowered. Moreover, this disclosure is particularly related to the construction of an antenna, which can be a three-dimensional wire antenna, so as to decrease the occupation area of an RFID tag on a PCB and further enhance its readability. It is noted that the RFID chip could be another type of integrated-circuit (IC) chip also, to build up a PCB device with an antenna.

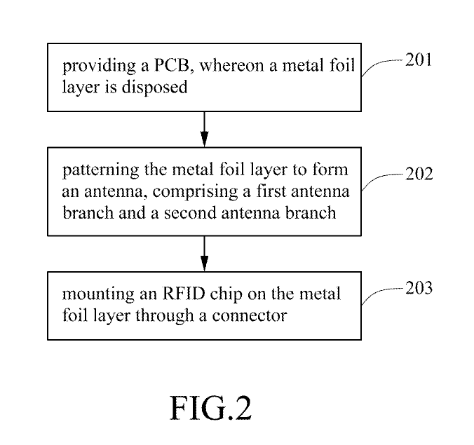

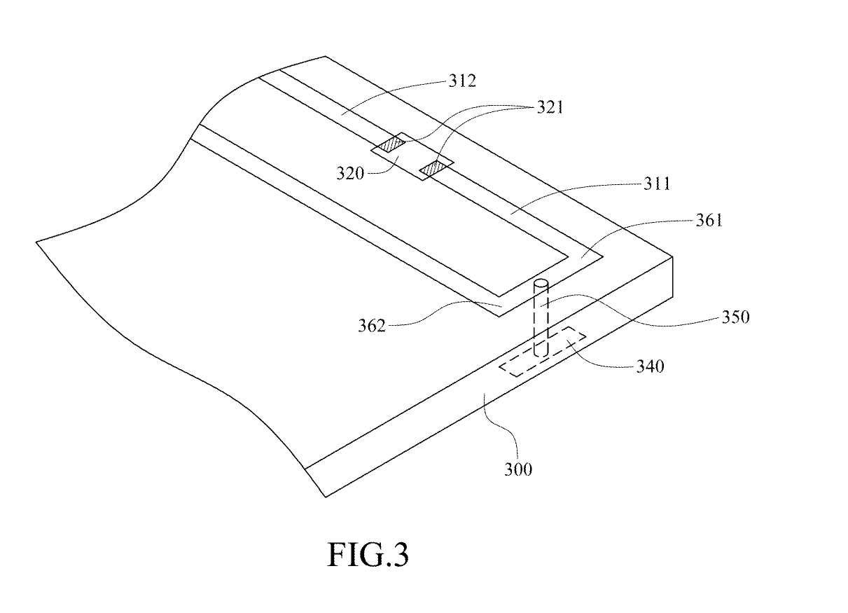

FIG. 2 illustrates a flowchart of a method for manufacturing a PCB with an antenna for an RFID chip, according to an embodiment. FIG. 3 schematically illustrates a perspective view of a PCB with an antenna for an RFID chip, according to an embodiment. This disclosure comprises the following steps. At step 201, a PCB 300 with a metal foil layer is provided. The metal foil layer is generally disposed on an outer layer of the PCB. At step 202, the metal foil layer is patterned to form an antenna. The antenna comprises a first antenna branch 311 and a second antenna branch 312, wherein the first antenna branch 311 has at least two right-angle turns 361/362. At step 203, an RFID chip 320 is provided and mounted on the metal foil layer through a connector 321, so as to electrically connect the first antenna branch 311 and the second antenna branch 312. In order to resist the effect of metal interference on the RFID chip 320, a via hole 350 is formed in the PCB between the right-angle turns of the first antenna branch, so that the first antenna branch is electrically connected to a metal conductor 340 inside or on the back of the PCB through the via hole 350. Accordingly, an RFID tag with high directionality combined with the embodiment of the invention is applicable to the circumstance of rich metal interference, and the high-frequency performance thereof is not going to descend. Adjusting the position of the via hole 350 can be used to match harmonic frequency with impedance of the antenna 110.

For the first antenna branch in a preferable embodiment, the length between the RFID chip 320 and the most adjacent turn 361 to the RFID chip is at least one fifth length of the first antenna branch 311. Preferably the RFID chip 320 is packaged in a form of the conventional SOP, and is with 17 to 30 ohm impedance. Preferably the RFID chip 320 is mounted on the PCB by the SMT. In addition, the metal conductor 340 inside or on the back of the PCB can be connected to a ground plane so as to be grounded electrically.

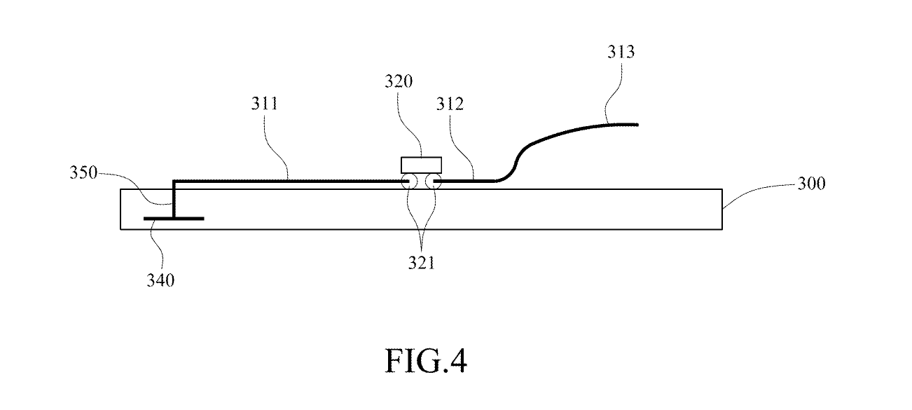

In another embodiment, the second antenna branch 312 has two turns to form a PIFA (Planar inverted F antenna)-like antenna. However, to decrease occupation area of an antenna on a PC and electromagnetic interference due to that the antenna is close to the PCB, a three-dimensional antenna structure is provided according to another embodiment. FIG. 4 illustrates a side view of a PCB with a three-dimensional antenna for an RFID chip, according to the embodiment. The second antenna branch 312 can be a wire to connect electrically with a lead 313 with an appreciate length, so that the lead 313 is off-board from the PCB 300. Consequently, the occupation area of the RFID antenna on a PCB is decreased, the issue of electromagnetic interference is improved, and thereby the readability is increased.

The disclosure being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for manufacturing a printed circuit board (PCB) with an antenna, comprising:
providing a PCB, whereon a metal foil layer is disposed;
patterning the metal foil layer to form an antenna, the antenna further comprising a first antenna branch and a second antenna branch, wherein the first antenna branch has at least two right-angle turns; and
mounting an RFID chip on the metal foil layer so as to electrically connect the first antenna branch and the second antenna branch;
wherein a via hole is formed in the PCB between the right-angle turns of the first antenna branch, so that the first antenna branch is electrically connected to a metal conductor inside or on the back of the PCB through the via hole.

2. The method of claim 1, wherein a distance between the RFID chip and the most adjacent turn to the RFID chip is at least one fifth length of the first antenna branch.

3. The method of claim 1, wherein the RFID chip is packaged in a form of the small outline package (SOP).

4. The method of claim 1, wherein the RFID chip is mounted on the PCB by the surface mounting technology (SMT).

5. The method of claim 1, wherein the metal conductor is connected to a ground plane.

6. The method of claim 1, wherein the second antenna branch has at least two turns.

7. The method of claim 1, wherein the second antenna branch behaves as a wire and connects electrically to an off-board lead.

8. An RFID apparatus, comprising:
a PCB with a patterned metal foil layer thereon as an antenna, the antenna comprising a first antenna branch and a second antenna branch, wherein the first antenna branch has at least two right-angle turns;
an RFID chip, mounted on the metal foil layer so as to electrically connect the first antenna branch and the second antenna branch; and
a via hole in the PCB and between the right-angle turns of the first antenna branch, so as to electrically connect the first antenna branch and a metal conductor inside or on the back of the PCB through the via hole.

9. The RFID apparatus of claim 8, wherein a distance between the RFID chip and the most adjacent turn to the RFID chip is at least one fifth length of the first antenna branch.

10. The RFID apparatus of claim 8, wherein the RFID chip is packaged in a form of the small outline package (SOP).

11. The RFID apparatus of claim 8, wherein the RFID chip is mounted on the PCB by the surface mounting technology (SMT).

12. The RFID apparatus of claim 8, wherein the metal conductor is connected to a ground plane.

13. The RFID apparatus of claim 8, wherein the second antenna branch has at least two turns.

14. The RFID apparatus of claim 8, wherein the second antenna branch behaves as a wire and connects electrically to an off-board lead.

15. A PCB device with an antenna, comprising:
a PCB with a patterned metal foil layer thereon as the antenna, the antenna comprising a first antenna branch and a second antenna branch, wherein the first antenna branch has at least two right-angle turns;
an integrated-circuit (IC) chip, mounted on the metal foil layer so as to electrically connect the first antenna branch and the second antenna branch; and
a via hole in the PCB and between the right-angle turns of the first antenna branch, so as to electrically connect the first antenna branch and a metal conductor inside or on the back of the PCB through the via hole.

16. The PCB device of claim 15, wherein a distance between the IC chip and the most adjacent turn to the IC chip is at least one fifth length of the first antenna branch.

17. The PCB device of claim 15, wherein the IC chip is packaged in a form of the SOP and mounted on the PCB by the SMT.

18. The PCB device of claim 15, wherein the metal conductor is connected to a ground plane.

19. The PCB device of claim 15, wherein the second antenna branch has at least two turns.

20. The RFID apparatus of claim 8, wherein the second antenna branch behaves as a wire and connects electrically to an off-board lead.
